(19) United States
(12) Patent Application Publication
(10) Pub. No.: US 2016/0054421 A1
(43) Pub. Date: Feb. 25, 2016

(54) METHOD FOR CALIBRATING A SHORT CIRCUIT INDICATOR WITH DIRECTION DETECTION AND SHORT CIRCUIT INDICATOR TO USE SUCH A METHOD

(71) Applicant: DIRK HORSTMANN, DUSSELDORF (DE)

(72) Inventor: DIRK HORSTMANN, DUSSELDORF (DE)

(73) Assignee: DIPL.-ING. H. HORSTMANN GMBH, Heiligenhaus (DE)

(21) Appl. No.: 14/447,343

(22) Filed: Aug. 19, 2014

(51) Int. Cl. G01R 35/00; G01R 31/02

(52) U.S. Cl. CPC G01R 35/005; G01R 31/025

(57) ABSTRACT

The present invention relates to a method for calibrating a short-circuit indicator (1) for identifying a short circuit and/or a ground fault in a connected voltage grid (5) by means of an evaluation unit (3). A calibration unit (2) automatically measures at least one value of the currents and/or the voltages of the phases (1A, 1B, 1C) of the voltage grid (5), which value is characteristic of the normal operation of the voltage grid (5), and checks whether the measured characteristic value is within a validity range characterizing the normal operation. The calibration unit (2), in the event of successful checking, measures the normal values of the voltages and/or the currents of all phases (1A, 1B, 1C) of the voltage grid (5) and makes these normal values available to the evaluation unit (3) for identification of the short circuit and/or the ground fault and the direction of the fault location in the voltage grid (5). In addition, the invention comprises a short-circuit indicator (1) for applying a method according to the invention.

The present invention relates to a method for calibrating a short-circuit indicator for identifying a short circuit and/or a ground fault in a connected voltage grid by means of an evaluation unit.

Within the meaning of the invention, the term short-circuit indicator also includes ground-fault indicator and associated devices and device functions which detect short circuits, ground faults and particular operating states, in particular in electrical medium-voltage grids, in order to make said short circuits, ground faults and particular operating states available for providing an indication, message, for initiating an action or for further processing.

A known short-circuit indicator is described, for example, in DE 10 2007 007 167 A1.

Such short-circuit indicators are used to identify a short circuit in the voltage grid and to determine the direction of the short circuit in the voltage grid on the basis of the position of the short-circuit indicator in the voltage grid, with the result that the cause of the short circuit can be found more quickly. This is in particular advantageous especially when decentralized feeds take place in the voltage grid, for example by means of photovoltaic plants or wind farm installations, since in this case there is a feed to the fault from two directions, with the result that the fault location cannot be found easily by simple short-circuit indicators without any directional information.

Such short-circuit indicators require precise information relating to the normal values of the operating current intensity and the operating voltage of the individual phases of the connected voltage grid for the directional determination of the short circuit. These values are measured by means of sensors of the evaluation unit during normal operation of the voltage grid, with the result that the evaluation unit can be calibrated in each case for the connected voltage grid. With the known short-circuit indicators, this takes place manually by virtue of the user observing the voltage grid and determining, on the basis of a plurality of measured variables, whether there is normal operation. If the user comes to the conclusion that there is normal operation, said user initiates a calibration mode, as a result of which the short-circuit indicator is calibrated to the present normal values of the voltage grid.

Such a method is complex since it presupposes a level of technical knowledge of the user and requires manual interaction by the user.

The present invention is based on the object of providing a method for calibrating a short-circuit indicator and a short-circuit indicator with directional determination, in which the calibration for the connected voltage grid can be implemented in a manner which is as simple, reliable and quick as possible.

The object is achieved according to the invention by a method for calibrating a short-circuit indicator for identifying a short circuit and/or a ground fault in a connected voltage grid by means of an evaluation unit, wherein a calibration unit automatically measures at least one value of the currents and/or the voltages of the phases of the voltage grid, which value is characteristic of the normal operation of the voltage grid and checks whether the measured characteristic value is within a validity range characterizing the normal operation, wherein the calibration unit, in the event of successful checking, measures the normal values of the voltages and/or the currents of all phases of the voltage grid and makes these normal values available to the evaluation unit for identification of the short circuit and/or the ground fault and the direction of the fault location in the voltage grid.

In addition, the object is achieved by a short-circuit indicator, which comprises an evaluation unit which can be calibrated by means of normal values for the currents and/or voltages of the phases of a connected voltage grid for the voltage grid, identifies the occurrence and direction of position of a short circuit and/or a ground fault in the voltage grid by means of current and/or voltage sensors, and has a calibration unit for implementing the above method.

By virtue of the automatic checking of a characteristic value for the normal operation of the voltage grid, the short-circuit indicator can be calibrated independently and automatically, with the result that no interaction of a user for bringing the short-circuit indicator into operation is required.

In an advantageous embodiment of the invention, the calibration unit, over a specific time period, repeats a plurality of measurement and check cycles and determines steady-state mean values for the normal values for the time period and makes these mean values available to the evaluation unit for identification of the short circuit and/or the ground fault and the direction of the fault location in the voltage grid. This enables more precise determination of the normal values independently of time-specific deviations as a result of abnormal loads.

Further embodiments and advantageous configurations of the invention are described in the description of the figures and the dependent claims.

In the figures:

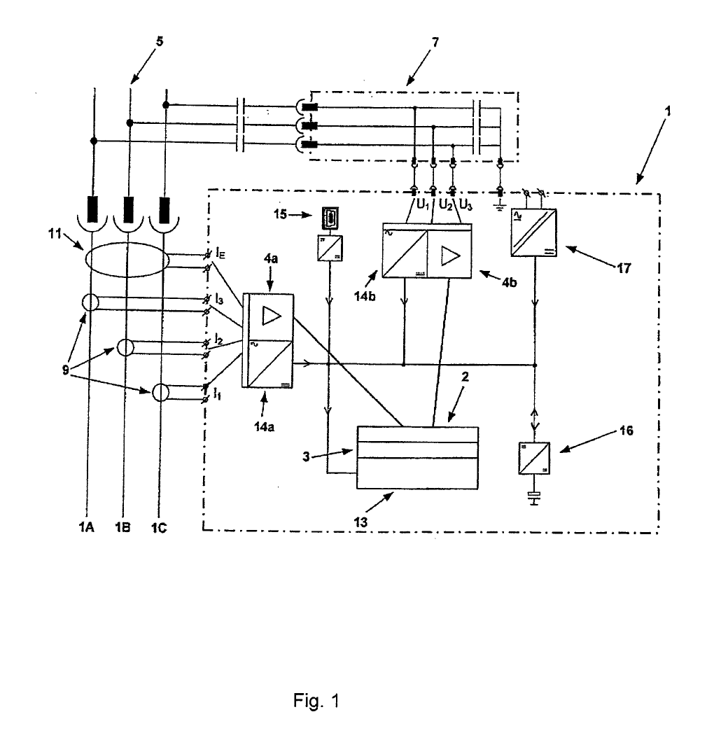

FIG. 1 shows a connection diagram of a short-circuit indicator according to the invention,

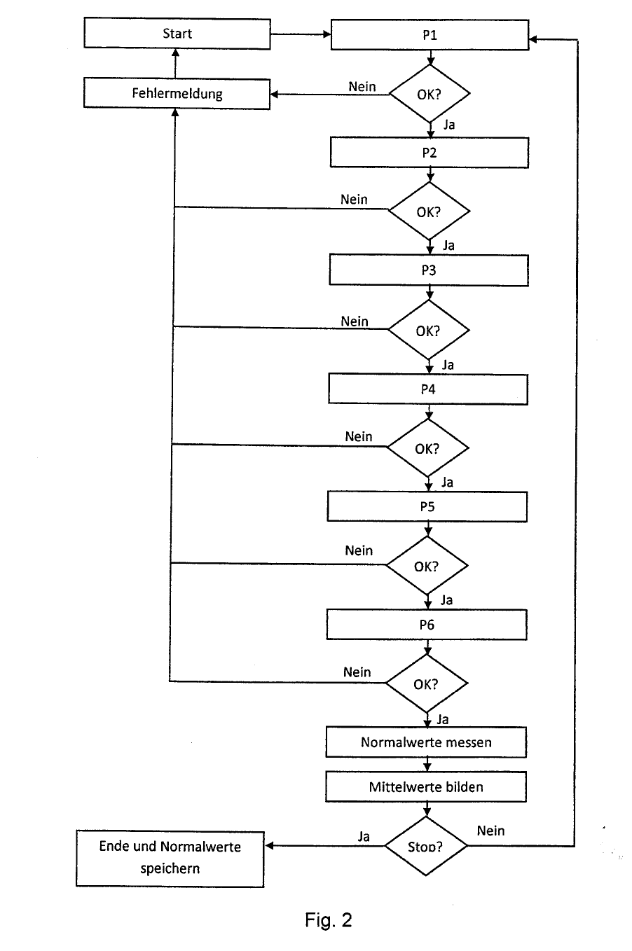

FIG. 2 shows a flow chart of the calibration of a short-circuit indicator according to the invention.

In the various figures in the drawing, identical parts have always been provided with the same reference symbols.

With respect to the description which follows, it is claimed that the invention is not restricted to the exemplary embodiments and also not to all or several features of described feature combinations, but rather each individual subfeature of the/each exemplary embodiment is also detached from all other subfeatures described in connection therewith individually and also in combination with any desired features of another exemplary embodiment of significance to the subject matter of the invention.

FIG. 1 shows a connection diagram of a short-circuit indicator 1 according to the invention. The short-circuit indicator 1 comprises an evaluation unit 3, which, via current and voltage sensors connected to the short-circuit indicator, identifies a short circuit or a ground fault in a voltage grid 5, in particular a three-phase medium-voltage grid, and determines the direction of the fault location on the basis of the position of the short-circuit indicator 1. For this purpose, during operation of the short-circuit indicator 1, voltage interfaces U1, U2, U3 of the short-circuit indicator 1 are connected, via a capacitive voltage divider 7, by means of voltage sensors to the phases 1A, 1B, 1C of the voltage grid 5. In addition, during operation, current interfaces I1, I2, I3 of the short-circuit indicator are connected to the phases 1A, 1B, 1C of the voltage grid 5 via inductive measuring transducers 9. Alternatively or in addition, a current interface IE can be connected to the voltage grid 5 via an inductive summation current measuring transducer 11.

The short-circuit indicator 1 additionally comprises, as part of the evaluation unit 3, a microcontroller 13 comprising a memory and comprising analog-to-digital converters, which convert the measured currents and voltages into digital values, by means of which the measured values at the current interfaces I1, I2, I3, IE and/or the voltage interfaces U1, U2, U3 can be evaluated and the short circuit and/or the ground fault and the direction thereof can be determined. For this purpose, the short-circuit indicator 1 continuously measures and checks the present currents and/or voltages of the phases 1A, 1B, 1C of the voltage grid 5 and, in the event of the occurrence of specific changes in the currents and/or voltages, identifies the short circuit and/or the ground fault. In order that reliable fault identification and direction determination is possible, the evaluation unit 3 compares the present currents and/or voltages of the phases 1Ab, 1B, 1C with normal values for the normal operation of the voltage grid 5 stored in the memory of the microcontroller 13. In this case, the normal values are matched precisely to the connected voltage grid 5 and the normal operation thereof, with the result that the short-circuit indicator 1 is calibrated for the connected voltage grid 5.

The short-circuit indicator 1 according to the invention comprises a calibration unit 2, which can be integrated in particular with the evaluation unit 3 in the microcontroller 13. The calibration unit 2 is connected to the current interfaces I1, I2, I3 and/or the voltage interfaces U1, U2, U3. For this purpose, input stages 4a, 4b are interposed in particular between the current interfaces I1, I2, I3, IE and the voltage interfaces U1,U2, U3, which input stages scale the phase currents and/or phase voltages of the voltage grid 5 correspondingly, with the result that they can be processed by the calibration unit 2 and the evaluation unit 3 and in particular by the analog-to-digital converters and the microprocessor 13. The calibration unit 2 determines the normal values of the phase currents and/or the phase voltages independently, i.e. without any action by a user, during normal operation of the voltage grid 5. After successful calibration, the evaluation unit 3 uses the normal values determined by the calibration unit 2 for the identification of the short circuit and/or the ground fault and the direction of the fault in the voltage grid 5.

After the start of the calibration by a voltage supply 15, 16, 17 to the short-circuit indicator 1 being switched on or by the voltage grid 5 being connected to the short-circuit indicator 1, the calibration unit 2 measures at least one value for the voltages and/or the currents in the phases 1A, 1B, 1C which is characteristic of the normal operation of the voltage grid at the voltage interfaces U1, U2, U3 and/or the current interfaces I1, I2, I3, IE. The measured characteristic value is compared with validity ranges stored in the memory for the normal operation of specific voltage grids 5, with the result that the calibration unit 2 first establishes whether the connected voltage grid 5 is undergoing normal operation. If all of the measured characteristic values are in the validity ranges for the normal operation, the normal values required for the calibration, in particular the phase voltages and the phase angles of the currents and/or the voltages of the individual phases 1A, 1B, 1C, are measured and stored in the memory for subsequent use by the evaluation unit 3. If one of the measured characteristic values is not in its validity range, the calibration is terminated. Advantageously, in this case a fault message indicating that calibration is not possible is output to the user by the short-circuit indicator 1.

In one embodiment of the short-circuit indicator 1, the short-circuit indicator 1 comprises a voltage converter 14a, 14b, which comprises a rectifier and makes available the energy supply to the short-circuit indicator 1 from the voltage grid 5 connected via the current interfaces I1, I2, I3, IE or the voltage interfaces U1, U2, U3.

In a further advantageous configuration of the short-circuit indicator 1, the short-circuit indicator 1 has an energy store 16, in particular a battery or a rechargeable battery, which is chargeable in particular by the energy supply to the short-circuit indicator 1, and makes available the required energy for the short-circuit indicator 1 in particular in the event of isolation of the energy supply.

In a further embodiment of a short-circuit indicator 1 according to the invention, the short-circuit indicator 1 comprises a communications interface, in particular a USB port 15, via which the energy supply to the short-circuit indicator 1 can be made available by an external voltage source.

Advantageously, the short-circuit indicator 1 comprises a voltage converter 17 for connection of an external energy source.

FIG. 2 shows a flowchart of a method according to the invention for calibrating a short-circuit indicator 1 according to the invention. The method illustrated here comprises checks performed on a plurality of characteristic values with a validity range appropriate for the respective characteristic value for the normal operation of the voltage grid. According to the invention, at least one of these values needs to be checked so that the calibration unit 2 can identify normal operation. The more checks on different characteristic values are performed, the more reliably the normal operation can be identified. Accordingly, any desired combination of checks of various characteristic values is possible according to the invention.

The calibration starts independently, i.e. without any action by a user, once the short-circuit indicator 1 has been connected to the voltage grid 5 or once a voltage supply 14a, 14b, 15, 16, 17 to the short-circuit indicator 1 has been switched on.

In a first check P1 of the calibration unit 2 according to the invention, the magnitude of the voltage and/or the current of the individual phases 1A, 1B, 1C is measured and compared with a validity range for the magnitude during normal operation.

In a second check P2 of the calibration unit 2 according to the invention, the voltage difference and/or the current difference between two phases 1A, 1B, 1C are measured and compared with a validity range for the difference during normal operation.

In a third check P3 of the calibration unit 2 according to the invention, the phase sequence of the measured voltages and/or currents in the individual phases 1A, 1B, 1C is determined and compared with a valid stored phase sequence during normal operation, in particular the phase sequence 0°-120°-240°.

In a fourth check P4 of the calibration unit 2 according to the invention, the phase angle of the measured voltages and/or currents of the individual phases 1A, 1B, 1C is determined and compared with a stored validity range for the phase angle during normal operation.

In a fifth check P5 of the calibration unit 2 according to the invention, the displacement voltage UNE of the phases 1A, 1B, 1C is determined and compared with a validity range for the displacement voltage during normal operation.

In a sixth check P6 of the calibration unit 2 according to the invention, the ground current of the phases 1A, 1B, 1C is determined and compared with a validity range for the phase-to-ground current during normal operation.

In accordance with the invention, once normal operation has been determined by the calibration unit 2, a single measurement of the normal values, in particular the phase voltages and the phase angles of the currents and/or the voltages of the individual phases, is sufficient for making available valid normal values for the voltage grid 5 for the evaluation unit.

The normal values can fluctuate over a certain time during normal operation, however, since the load on the voltage grid 5 can differ greatly depending on the time of day, for example. By repeating the measurement several times and performing statistical averaging of the valid normal values, the deviations in the valid normal values can be compensated for statistically, with the result that the accuracy of the normal values can be improved. In particular, the calibration is performed by the calibration unit 2 over a time period of 24 hours. After the measurement of the last valid normal value and the ultimate determination of the statistical normal values, for example as mean values of all measured valid normal values, the statistical normal value at the end of the time period is stored in the memory for use by the evaluation unit 3.

The invention is not restricted to the exemplary embodiments illustrated and described, but also includes all embodiments with an equivalent effect within the meaning of the invention. It is expressly emphasized that the exemplary embodiments are not restricted to all features in combination, but rather each individual subfeature can also individually have an inventive meaning separately from all other subfeatures. In addition, the invention as yet is also not restricted to the combination of features defined in Claim 1, but can also be defined by any other desired combination of specific features of all of the individual features disclosed as a whole. This means that, in principle, practically any individual feature of Claim 1 can be omitted or can be replaced by at least one individual feature disclosed at another point in the application.

1. Method for calibrating a short-circuit indicator (1) for identifying a short circuit and/or a ground fault in a connected voltage grid (5) by means of an evaluation unit (3),
wherein a calibration unit (2) automatically measures at least one value of the currents and/or the voltages of the phases (1A, 1B, 1C) of the voltage grid (5), which value is characteristic of the normal operation of the voltage grid (5) and checks whether the measured characteristic value is within a validity range characterizing the normal operation,
wherein the calibration unit (2), in the event of successful checking, measures the normal values of the voltages and/or the currents of all phases (1A, 1B, 1C) of the voltage grid (5) and makes these normal values available to the evaluation unit (3) for identification of the short circuit and/or the ground fault and the direction of the fault location in the voltage grid (5).

2. Method according to claim 1,
characterized in that
the magnitude and phase angles of the voltages and/or the currents of the phases (1A, 1B, 1C) are measured as normal values of the voltage grid (5).

3. Method according to claim 1,
characterized in that
the calibration unit (2), over a specific time period, repeats a plurality of measurement and check cycles and determines steady-state mean values for the normal values for the time period and makes these mean values available to the evaluation unit (3) for identification of the short circuit and/or the ground fault and the direction of the fault location in the voltage grid (5).

4. Method according to claim 1,
characterized in that
the calibration unit (2) terminates the determination of the normal values when the check performed on at least one characteristic value is faulty.

5. Method according to claim 1,
characterized in that
the calibration unit (2) checks, as characteristic value for the normal operation, a voltage difference and/or a current difference between two phases against a maximum value.

6. Method according to claim 1,
characterized in that
the calibration unit (2) checks, as characteristic value for the normal operation, a phase sequence of the currents and/or the voltages of the phases (1A, 1B, 1C) against a valid phase sequence.

7. Method according to claim 1,
characterized in that
the calibration unit (2) checks, as characteristic value for the normal operation, a phase angle of the currents and/or the voltages of the phases (1A, 1B, 1C) against a maximum phase deviation.

8. Method according to claim 1,
characterized in that
the calibration unit (2) checks, as characteristic value for the normal operation, a displacement voltage of the phases (1A, 1B, 1C) against a maximum value.

9. Method according to claim 1,
characterized in that
the calibration unit (2) checks, as characteristic value for the normal operation, a phase-to-ground current of a phase (1A, 1B, 1C) against a maximum value.

10. Method according to claim 1,
characterized in that
the calibration unit (2) outputs a fault message when it prematurely terminates the determination of the normal values.

11. Short-circuit indicator (1), comprising an evaluation unit (3), which can be calibrated by means of normal values for the currents and/or voltages of the phases (1A, 1B, 1C) of a connected voltage grid (5) for the voltage grid (5) and identifies the occurrence of and the positional direction of a short circuit and/or a ground fault in the voltage grid (5),
characterized by
a calibration unit (2) for implementing the method according to one of claims 1 to 10.

12. Short-circuit indicator according to claim 11,
characterized by
a voltage converter (14a, 14b), which makes available the energy supply to the short-circuit indicator (1) from the connected voltage grid (5).

13. Short-circuit indicator according to claim 11,
characterized by
a communications interface (15), via which an external voltage supply to the short-circuit indicator (1) can be connected.

14. Short-circuit indicator according to claim 11,
characterized by
an energy store (16), in particular a battery or a chargeable battery, which in particular can be charged by the energy supply to the short-circuit indicator (1), which in particular makes available the required energy for the short-circuit indicator (1) in the event of isolation of the energy supply.

15. Short-circuit indicator according to claim 11,
characterized by
a voltage converter (17) for connection of an external energy source for the operation of the short-circuit indicator (1).
